(19) United States
(12) Patent Application Publication
(10) Pub. No.: US 2025/0247081 A1
(43) Pub. Date: Jul. 31, 2025

(54) ACOUSTIC WAVE FILTER HAVING ACOUSTIC REFLECTORS WITH ADJUSTED PITCHES

(71) Applicant: SKYWORKS SOLUTIONS, INC., Irvine, CA (US)

(72) Inventor: Akira Ochiai, Suita-Shi (JP)

(21) Appl. No.: 19/034,817

(22) Filed: Jan. 23, 2025

Related U.S. Application Data
(60) Provisional application No. 63/626,652, filed on Jan. 30, 2024.

(51) Int. Cl. H03H 9/64; H03F 3/24; H03H 9/02; H03H 9/25

(52) U.S. Cl. CPC H03H 9/6483; H03H 9/02559; H03H 9/25; H03F 3/245; H03F 2200/451

(57) ABSTRACT

In certain embodiments, the present disclosure relates to an acoustic wave filter. The acoustic wave filter includes a plurality of first surface acoustic wave (SAW) resonators. Each of the plurality of first SAW resonators includes a piezoelectric substrate, interdigital transducer electrodes, and acoustic reflectors. The acoustic reflectors have different pitch distances that are adjusted in such a way that the frequency gaps between resonant frequencies of the plurality of first SAW resonators outside the passband of the acoustic wave filter are equalized.

### CROSS-REFERENCE TO RELATED APPLICATIONS

This application claims priority under 35 U.S.C. § 119 (e) to U.S. Provisional Patent Ser. No. 63/626,652, titled “ACOUSTIC WAVE FILTER HAVING ACOUSTIC REFLECTORS WITH ADJUSTED PITCHES,” filed Jan. 30, 2024, the entire content of which is incorporated herein by reference for all purposes.

### BACKGROUND

### Field

Aspects and embodiments disclosed herein relate to electronic systems, and in particular, to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about 410 MHz to about 7.125 GHz for fifth generation (5G) frequency range 1 (FR1) communications and in the range of about 24.25 GHz to about 52.6 GHz for 5G frequency range 2 (FR2) communications.

Examples of RF communication systems include, but are not limited to, mobile phones, tablets, base stations, network access points, customer-premises equipment (CPE), laptops, and wearable electronics.

### SUMMARY

In certain embodiments, the present disclosure relates to an acoustic wave filter. The acoustic wave filter includes a plurality of first surface acoustic wave (SAW) resonators. Each of the plurality of first SAW resonators includes a piezoelectric substrate, interdigital transducer electrodes, and acoustic reflectors. The acoustic reflectors have different pitch distances that are adjusted in such a way that the frequency gaps between resonant frequencies of the plurality of first SAW resonators outside the passband of the acoustic wave filter are equalized.

In certain other embodiments, the present disclosure relates to an acoustic wave filter. The acoustic wave filter includes a plurality of first surface acoustic wave (SAW) resonators. Each of the plurality of first SAW resonators includes a piezoelectric substrate, interdigital transducer electrodes, and acoustic reflectors. The acoustic reflectors have a number of electrodes with different electrode widths, the electrode widths of the acoustic reflectors being adjusted so that the frequency gaps between resonant frequencies of the plurality of first SAW resonators outside the passband of the acoustic wave filter are equalized.

In some embodiments, the piezoelectric substrate is a lithium tantalate or lithium niobate substrate. According to a number of embodiments, the piezoelectric substrate includes a lithium niobate crystal cut with a surface normal orientation of (α, β, γ), with α between −10° and +10°, β between −10° and +10°, and γ between 80° and 100° in Euler angles. In various embodiments, the surface normal orientation of the lithium niobate crystal is (α, β, γ)=(0°, 0°, 90°) in Euler angles.

In several embodiments, the plurality of first SAW resonators are series resonators. According to a number of embodiments, the acoustic wave filter further includes a plurality of second SAW resonators coupled in parallel to the plurality of first SAW resonators. In some embodiments thereof, the plurality of second SAW resonators are shunt resonators.

In various embodiments, the acoustic wave filter is a hybrid ladder-lattice-type acoustic wave filter. According to several embodiments, the acoustic wave filter is a ladder-type acoustic wave filter. In some embodiments, the frequency gaps between resonant frequencies of two neighboring resonators of the plurality of first SAW resonators outside the passband of the acoustic wave filter are substantially equal.

In certain embodiments, the present disclosure relates to a radio-frequency (RF) module. The RF module may in some embodiments be a RF transmit module. The RF module includes an RF antenna, a power amplifier coupled to the RF antenna and configured to amplify an RF signal for transmission by the RF antenna, and at least one acoustic wave filter. The acoustic wave filter includes a plurality of first surface acoustic wave (SAW) resonators. Each of the plurality of first SAW resonators includes a piezoelectric substrate, interdigital transducer electrodes, and acoustic reflectors. The acoustic reflectors have different pitch distances that are adjusted in such a way that the frequency gaps between resonant frequencies of the plurality of first SAW resonators outside the passband of the acoustic wave filter are equalized.

In some embodiments, the piezoelectric substrate is a lithium tantalate or lithium niobate substrate. According to a number of embodiments, the piezoelectric substrate includes a lithium niobate crystal cut with a surface normal orientation of (α, β, γ), with α between −10° and +10°, β between −10° and +10°, and γ between 80° and 100° in Euler angles.

In several embodiments, the plurality of first SAW resonators are series resonators. According to a number of embodiments, the acoustic wave filter further includes a plurality of second SAW resonators coupled in parallel to the plurality of first SAW resonators. In some embodiments thereof, the plurality of second SAW resonators are shunt resonators.

In various embodiments, the acoustic wave filter is a hybrid ladder-lattice-type acoustic wave filter. According to several embodiments, the acoustic wave filter is a ladder-type acoustic wave filter. In some embodiments, the frequency gaps between resonant frequencies of two neighboring resonators of the plurality of first SAW resonators outside the passband of the acoustic wave filter are substantially equal. In several embodiments, the at least one acoustic wave filter comprises a pre-amplifier acoustic wave filter coupled upstream of the power amplifier in transmit direction. According to a number of embodiments, the at least one acoustic wave filter comprises a post-amplifier acoustic wave filter coupled between the power amplifier and the RF antenna.

In certain embodiments, the present disclosure relates to a radio frequency (RF) front end module. The RF front end module includes an RF module. The RF module includes an RF antenna, a power amplifier coupled to the RF antenna and configured to amplify an RF signal for transmission by the RF antenna, and at least one acoustic wave filter. The acoustic wave filter includes a plurality of first surface acoustic wave (SAW) resonators. Each of the plurality of first SAW resonators includes a piezoelectric substrate, interdigital transducer electrodes, and acoustic reflectors. The acoustic reflectors have different pitch distances that are adjusted in such a way that the frequency gaps between resonant frequencies of the plurality of first SAW resonators outside the passband of the acoustic wave filter are equalized.

In several embodiments, the at least one acoustic wave filter comprises a pre-amplifier acoustic wave filter coupled upstream of the power amplifier in transmit direction. According to a number of embodiments, the at least one acoustic wave filter comprises a post-amplifier acoustic wave filter coupled between the power amplifier and the RF antenna.

In certain embodiments, the present disclosure relates to a mobile device. The mobile device includes an RF module. The RF module includes an RF antenna, a power amplifier coupled to the RF antenna and configured to amplify an RF signal for transmission by the RF antenna, and at least one acoustic wave filter. The acoustic wave filter includes a plurality of first surface acoustic wave (SAW) resonators. Each of the plurality of first SAW resonators includes a piezoelectric substrate, interdigital transducer electrodes, and acoustic reflectors. The acoustic reflectors have different pitch distances that are adjusted in such a way that the frequency gaps between resonant frequencies of the plurality of first SAW resonators outside the passband of the acoustic wave filter are equalized.

In various embodiments, the at least one acoustic wave filter comprises a pre-amplifier acoustic wave filter coupled upstream of the power amplifier in transmit direction. According to several embodiments, the at least one acoustic wave filter comprises a post-amplifier acoustic wave filter coupled between the power amplifier and the RF transmit antenna.

In certain embodiments, the present disclosure relates to a method of manufacturing an acoustic wave filter. The method includes mounting first interdigital transducer electrodes on a first piezoelectric substrate to form a first surface acoustic wave (SAW) resonator. The method further includes forming first acoustic reflectors in or on the first piezoelectric substrate, the first acoustic reflectors having a first pitch distance. The method further includes mounting second interdigital transducer electrodes on a second piezoelectric substrate to form a second SAW resonator. The method further includes forming second acoustic reflectors in or on the second piezoelectric substrate, the second acoustic reflectors having a second pitch distance adjusted so that the frequency gaps between resonant frequencies of the first and second SAW resonators outside the passband of the acoustic wave filter are equalized. The method additionally includes coupling the first SAW resonator and the second SAW resonator in series to form the acoustic wave filter.

In various embodiments, the method further includes coupling shunt acoustic wave resonators in parallel to the first and second SAW resonators.

In some embodiments, the acoustic wave filter is a hybrid ladder-lattice-type acoustic wave filter. In several embodiments, the acoustic wave filter is a ladder-type acoustic wave filter.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network;

FIG. 2A is a schematic diagram of one example of a communication link using carrier aggregation;

FIG. 2B illustrates various examples of uplink carrier aggregation for the communication link of FIG. 2A;

FIG. 2C illustrates various examples of downlink carrier aggregation for the communication link of FIG. 2A;

FIG. 3A is a schematic diagram of one example of a downlink channel using multi-input and multi-output (MIMO) communications;

FIG. 3B is schematic diagram of one example of an uplink channel using MIMO communications;

FIG. 3C is schematic diagram of another example of an uplink channel using MIMO communications;

FIG. 4A is a schematic diagram of one embodiment of a radio frequency (RF) module;

FIG. 4B is a schematic diagram of one embodiment of a radio frequency (RF) module that includes surface acoustic wave resonators;

FIG. 4C is a schematic diagram of another embodiment of a radio frequency (RF) module that includes surface acoustic wave resonators;

FIG. 5A is a simplified plan view of an embodiment of a surface acoustic wave resonator;

FIG. 5B is a simplified plan view of another embodiment of a surface acoustic wave resonator;

FIG. 5C is a simplified plan view of another embodiment of a surface acoustic wave resonator;

FIG. 6 is a cross-sectional view of a portion of a surface acoustic wave resonator having a piezoelectric substrate;

FIG. 7A illustrates as exemplary graph of the admittance values of a conventional acoustic wave filter;

FIG. 7B illustrates as exemplary graph of the admittance values of an acoustic wave filter having a number of SAW resonators with adjusted acoustic reflector pitches according to embodiments of this disclosure;

FIG. 8A illustrates as exemplary graph of the gain values of a conventional acoustic wave filter;

FIG. 8B illustrates as exemplary graph of the gain values of an acoustic wave filter having a number of SAW resonators with adjusted acoustic reflector pitches according to embodiments of this disclosure;

FIG. 9A is a schematic block diagram of a wireless communication device that includes filters that include one or more surface acoustic wave resonators according to some embodiments; and

FIG. 9B is a schematic block diagram of another wireless communication device that includes filters that include one or more surface acoustic wave resonators according to some embodiments.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings in which like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15, and Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

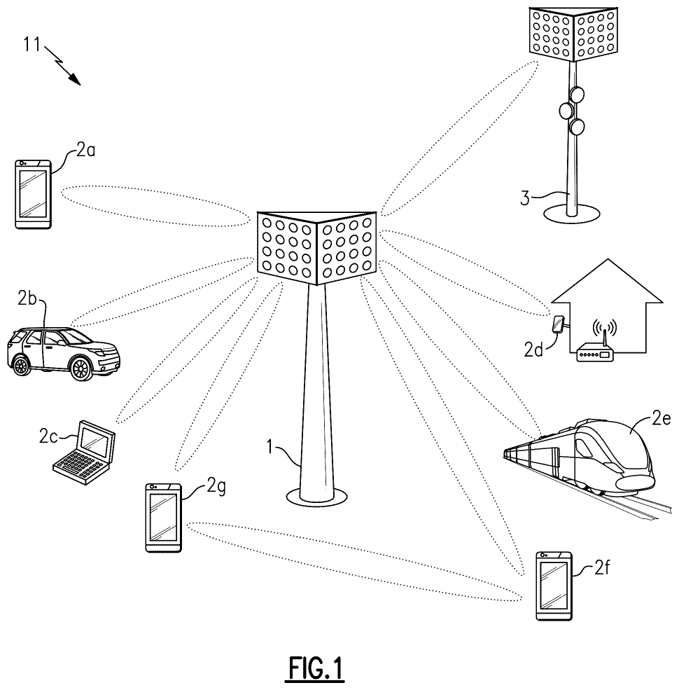

FIG. 1 is a schematic diagram of one example of a communication network 11. The communication network 11 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 11 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 11 is illustrated as including two base stations, the communication network 11 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 11 of FIG. 1 supports communications using a variety of cellular technologies, including, for example, 4G LTE and 5G NR. In certain implementations, the communication network 11 is further adapted to provide a wireless local area network (WLAN), such as WiFi. Although various examples of communication technologies have been provided, the communication network 11 can be adapted to support a wide variety of communication technologies.

Various communication links of the communication network 11 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 11 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 11 of FIG. 1 can be used to support a wide variety of advanced communication features, including, but not limited to, eMBB, uRLLC, and/or mMTC.

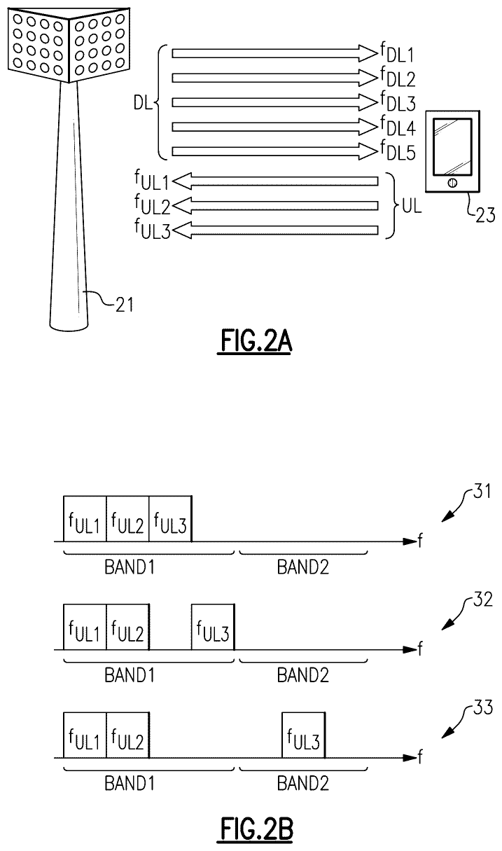

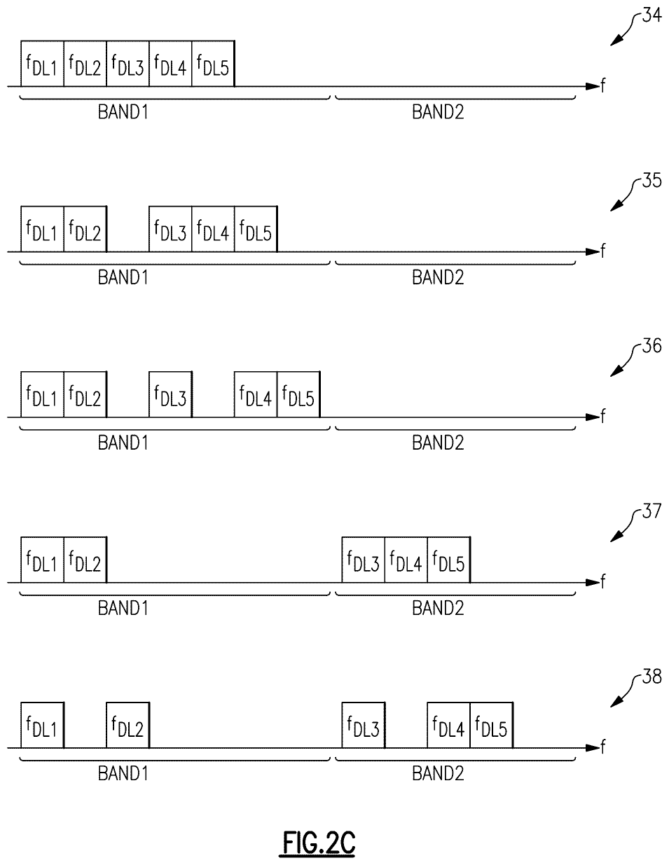

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 23. As shown in FIG. 2A, the communications link includes a downlink channel used for RF communications from the base station 21 to the mobile device 23, and an uplink channel used for RF communications from the mobile device 23 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 23 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As the number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink.

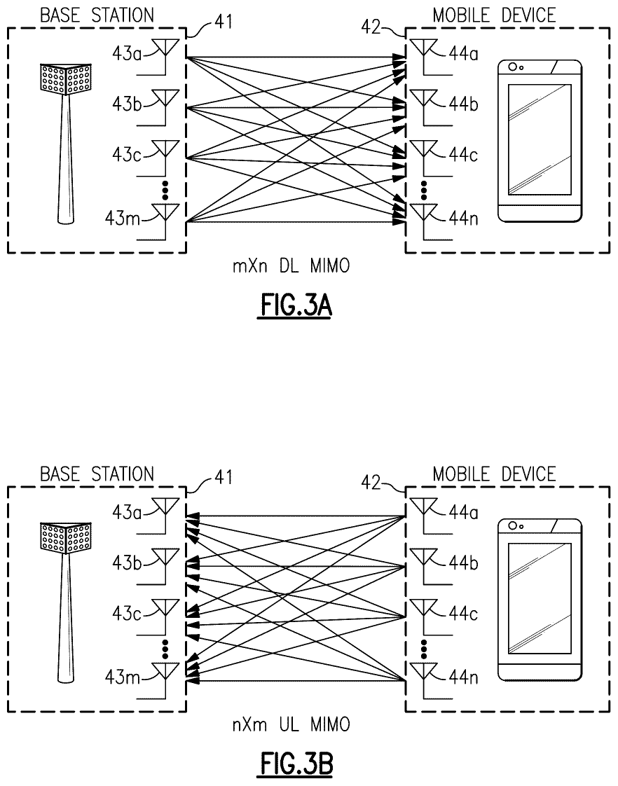

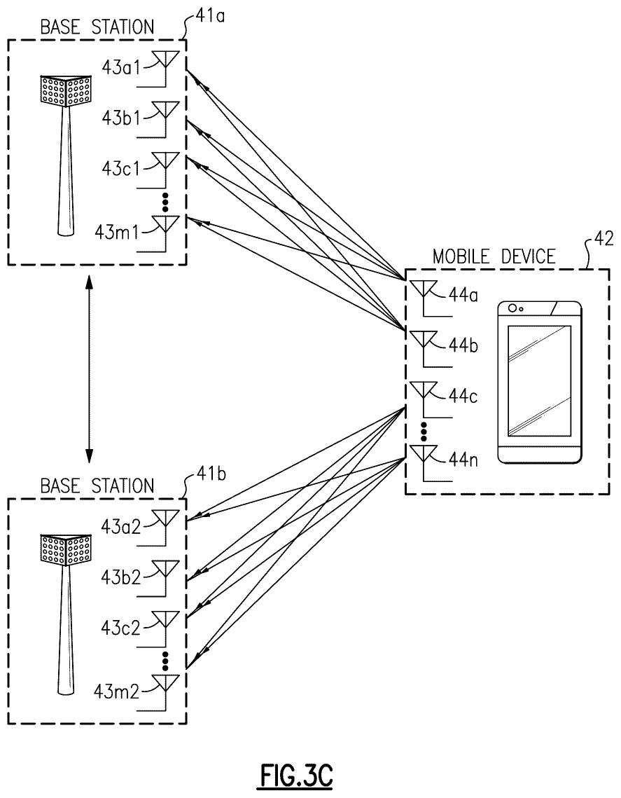

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communicate with one another over wired, optical, and/or wireless links.

The MIMO scenario of FIG. 3C illustrates an example in which multiple base stations cooperate to facilitate MIMO communications.

Uplink carrier aggregation (UL CA) combines two or more wireless (e.g., 5G) signals (component carriers), transmitted (uplinked) from a single user device to a wireless base station, dramatically increasing the speed with which a user can upload content and files. Similarly, downlink carrier aggregation (DL CA) combines two or more wireless (e.g., LTE) signals (component carriers), received (downlinked) by a single user device from a wireless base station, dramatically increasing the speed with which a user can download content and files. In the user device, front-end modules and architectures can be provided that support UL CA and/or DL CA.

Disclosed herein are, among others, examples related to front-end module designs that support CA, including considerations for: front-end module integration; power, gain, noise, and/or linearity budget for CA front-end modules; envelope tracking for CA; and passive integration including diplexers, duplexers, and/or filters. In particular, the front-end modules disclosed herein provide advantages in CA based at least in part on the combination of features provided by the modules. For example, the disclosed front-end modules include power amplifiers (PAs) for signals to be transmitted, low noise amplifiers (LNAs) for received signals, antenna switch modules, multiplexers (e.g., diplexers, triplexers, etc.), duplexers, and envelope tracking.

Particular advantages can be realized using the disclosed front-end modules. For example, some embodiments of the disclosed front-end modules include envelope tracking as part of the module. In some embodiments, envelope tracking may be included in a PA module to increase efficiency and/or to improve performance of the amplification path for signals to be transmitted. As another example, some embodiments of the disclosed front-end modules include band-specific filters and/or duplexers to process frequency division duplex (FDD) cellular frequency bands and time division duplex (TDD) frequency cellular bands. In certain implementations, a notch filter can be included on the front-end module to extract wireless local area network (WLAN) signals from the cellular frequency bands (e.g., from cellular band B40). As another example, some embodiments of the disclosed front-end modules include a bypass switch to provide a bypass path for transmission signals to bypass the PA module. As another example, some embodiments of the disclosed front-end modules include LNAs on the module to amplify received signals in a plurality of TDD cellular frequency bands. As another example, some embodiments of the disclosed front-end modules direct received signals in one or more FDD cellular frequency bands to a separate module for amplification to reduce degradation of signal quality on the front-end module.

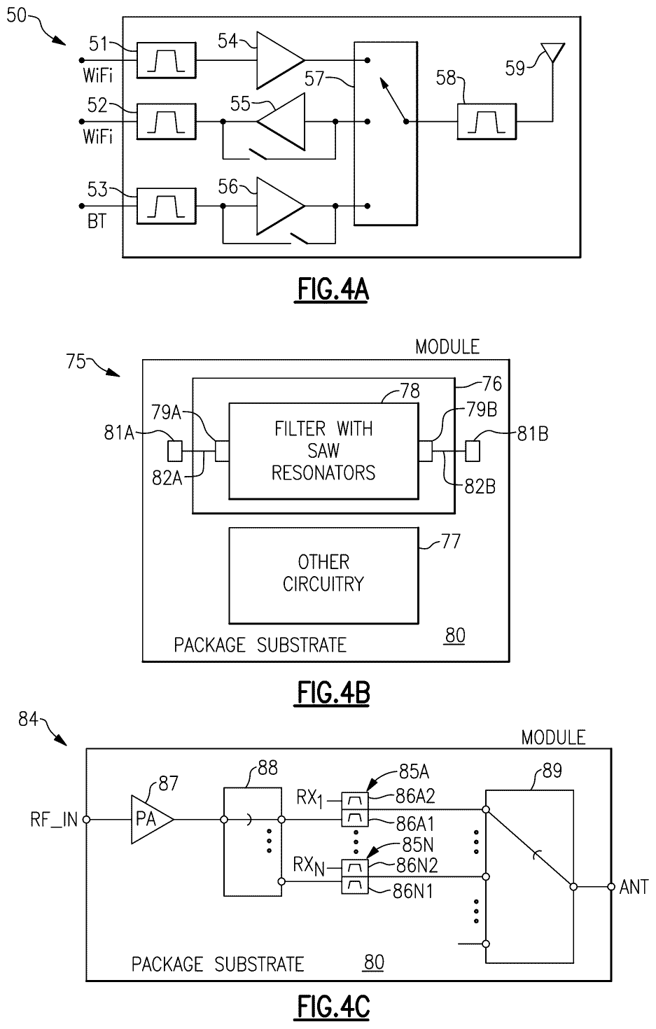

FIG. 4A illustrates an example of a radio-frequency (RF) module 50. The RF module 50 may for example be a RF transmit module. The RF module 50 includes a number of amplifiers, for example, a power amplifier 54, a power amplifier 56, and a low noise amplifier (LNA) 55. The power amplifier 54 and the LNA 55 are configured to process RF signals in a WiFi operating band, while the power amplifier 56 is configured to process RF signals in different operating band, such as for example an operating band for Bluetooth® communication. The RF module 50 further includes a number of band pass filters 51, 52, and 53 upstream of the amplifiers 54, 55, and 56.

The RF module 50 includes a multiplexer 57 coupled to the amplifiers 54, 55, and 56. The multiplexer 57 is configured to direct RF signals along a plurality of paths. The multiplexer 57 can be implemented as a switch and can include one or more poles and/or throws. The multiplexer 57 can be configured to receive RF signals from the amplifiers 54, 55, and 56 and to direct those received RF signals along a plurality of paths to targeted filters and/or duplexers for further processing, such as, for example, the filter 58 downstream of the amplifiers 54, 55, and 56. The RF module 50 includes an RF antenna 59 coupled to the filter 58 for transmission and/or reception of RF signals.

The band pass filters 51, 52, and 53 upstream of the amplifiers 54, 55, and 56 (also called “pre-amplifier filters”) as well as the filter 58 downstream of the multiplexer 57 (also called “post-amplifier filter”) need to be configured to reject RF transmission signals in a fairly wide frequency range outside of the passband of the respective filter. For band pass filters 51, 52, and 53 and filters 58 based on a plurality of surface acoustic wave (SAW) resonators, it would conventionally be necessary to increase the number of resonator stages in which each resonator stage includes at least one series SAW resonator and at least one shunt SAW resonator. However, increasing the number of resonator stages increases the size of the filter and, hence, the implementation costs.

Therefore, instead of increasing the number of resonator stages, it would be beneficial to equalize the reflector response of the plurality of series SAW resonators. This may be done by adjusting the pitch distances of the acoustic reflectors of each of the plurality of series SAW resonators. The pitch distance, in this case, refers to the distance from the center of one electrode to the center of the next in an acoustic reflector of a SAW resonator. The pitch distances of the acoustic reflectors of the plurality of series SAW resonators are adjusted so that the frequency gaps between resonant frequencies of the plurality of SAW resonators outside the passband of the filter are equalized. In particular, the adjustment of the pitch distances is implemented in such a manner that frequency gaps between resonant frequencies of two neighboring resonators of the plurality of series SAW resonators outside the passband of the filter are substantially equal.

FIG. 4B is a schematic diagram of a radio frequency module 75 that includes a surface acoustic wave component 76 according to an embodiment. The illustrated radio frequency module 75 includes the SAW component 76 and other circuitry 77. The SAW component 76 can include one or more SAW devices with any suitable combination of features of the SAW devices disclosed herein. Such SAW devices can include one or more SAW resonators, one or more SAW delay lines, one or more multi-mode SAW filters, or any suitable combination thereof. The SAW component 76 can include a SAW die that includes SAW resonators having adjusted pitch distances of their acoustic reflector electrodes.

The SAW component 76 shown in FIG. 4B includes a filter 78 and terminals 79A and 79B. The filter 78 includes SAW resonators. One or more of the SAW resonators can be implemented in accordance with any suitable principles and advantages of the surface acoustic wave resonators having adjusted pitch distances of their acoustic reflector electrodes as disclosed herein. The filter 78 can be a TC-SAW filter arranged as a band pass filter to filter radio frequency signals with frequencies below about 3.5 GHz in certain applications. The filter 78 may for example be a ladder-type filter or a hybrid ladder-lattice type lattice filter. The terminals 79A and 78B can serve, for example, as an input contact and an output contact. The SAW component 76 and the other circuitry 77 are on the same packaging substrate 80 in FIG. 4B. The package substrate 80 can be a laminate substrate. The terminals 79A and 79B can be electrically connected to contacts 81A and 81B, respectively, on the packaging substrate 80 by way of electrical connectors 82A and 82B, respectively. The electrical connectors 82A and 82B can be bumps or wire bonds, for example. The other circuitry 77 can include any suitable additional circuitry. For example, the other circuitry can include one or more power amplifiers, one or more radio frequency switches, one or more additional filters, one or more low noise amplifiers, the like, or any suitable combination thereof. The radio frequency module 75 can include one or more packaging structures to, for example, provide protection and/or facilitate easier handling of the radio frequency module 75. Such a packaging structure can include an overmold structure formed over the packaging substrate 75. The overmold structure can encapsulate some or all of the components of the radio frequency module 75.

FIG. 4C is a schematic diagram of a radio frequency module 84 that includes a surface acoustic wave component according to an embodiment. As illustrated, the radio frequency module 84 includes duplexers 85A to 85N that include respective transmit filters 86A1 to 86N1 and respective receive filters 86A2 to 86N2, a power amplifier 87, a select switch 88, and an antenna switch 89. The radio frequency module 84 can include a package that encloses the illustrated elements. The illustrated elements can be disposed on the same packaging substrate 80. The packaging substrate can be a laminate substrate, for example.

The duplexers 85A to 85N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 86A1 to 86N1 can include one or more SAW resonators in accordance with any suitable principles and advantages disclosed herein. Similarly, one or more of the receive filters 86A2 to 86N2 can include one or more SAW resonators in accordance with any suitable principles and advantages disclosed herein. Although FIG. 4C illustrates duplexers, any suitable principles and advantages disclosed herein can be implemented in other multiplexers (e.g., quadplexers, hexaplexers, octoplexers, etc.) and/or in switch-plexers.

The power amplifier 87 can amplify a radio frequency signal. The illustrated switch 88 is a multi-throw radio frequency switch. The switch 88 can electrically couple an output of the power amplifier 87 to a selected transmit filter of the transmit filters 86A1 to 86N1. In some instances, the switch 88 can electrically connect the output of the power amplifier 87 to more than one of the transmit filters 86A1 to 86N1. The antenna switch 89 can selectively couple a signal from one or more of the duplexers 85A to 85N to an antenna port ANT. The duplexers 85A to 85N can be associated with different frequency bands and/or different modes of operation (e.g., different power modes, different signaling modes, etc.)

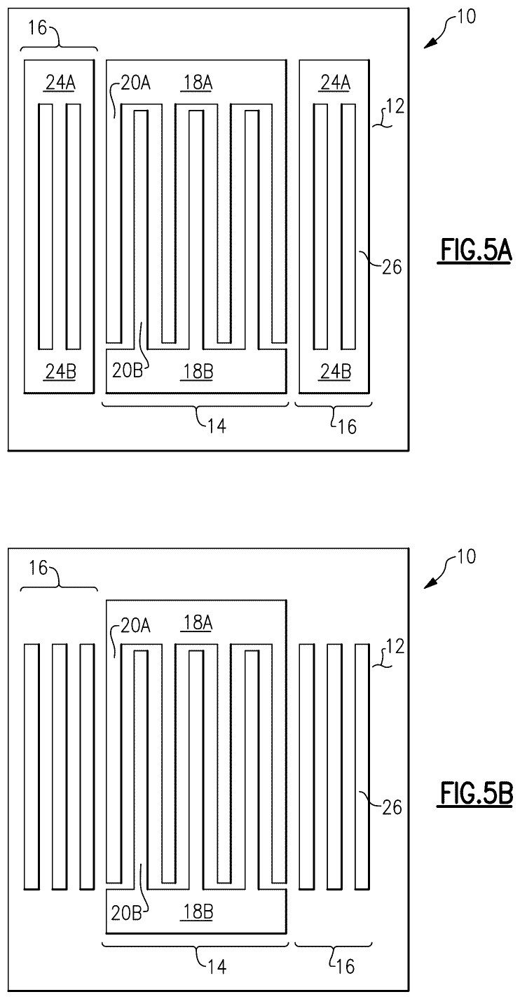

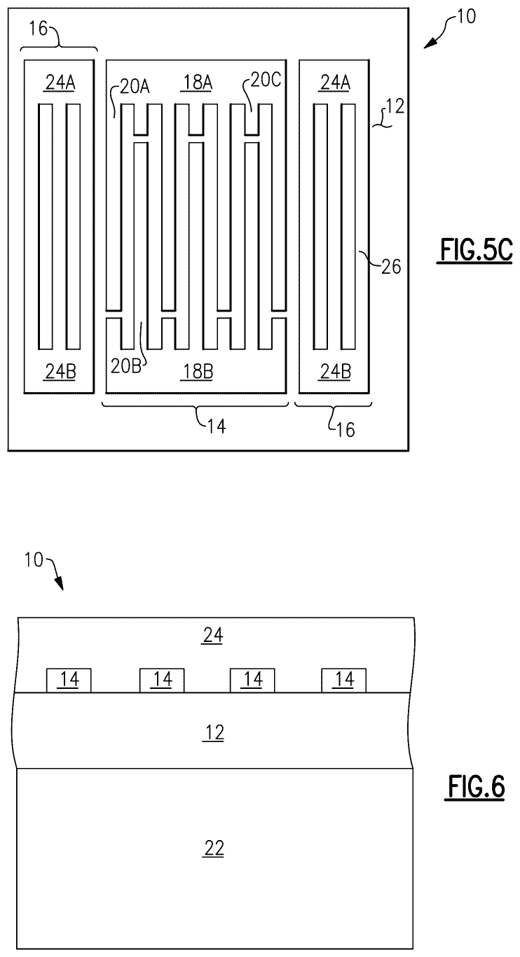

FIG. 5A is a plan view of a surface acoustic wave (SAW) resonator 10 such as might be used in a SAW filter, duplexer, diplexer, balun, etc.

The SAW resonator 10 is formed on a piezoelectric substrate, for example, a lithium tantalate (LiTaO₃) or lithium niobate (LiNbO₃) substrate 12 and includes Interdigital Transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing first bus bar electrode 18A. The bus bar electrodes 18A, 18B may be referred to herein together as busbar electrode 18. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B (collectively referred to herein as reflector bus bar electrode 24) and reflector fingers 26 extending between and electrically coupling the first bus bar electrode 24A and the second bus bar electrode 24B.

In other embodiments disclosed herein, as illustrated in FIG. 5B, the reflector bus bar electrodes 24A, 24B may be omitted and the reflector fingers 26 may be electrically unconnected. Further, as illustrated in FIG. 5C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

Using standard design techniques, the pitch of the reflector electrodes 16 would be directly proportional to the pitch of the IDT electrodes 14. The pitch of the IDT electrodes 14 determines the resonant and anti-resonant frequencies of the SAW resonator 10 overall. The entirety of the resonant and anti-resonant frequencies of a number of SAW resonators 10 in turn dominates the passband response of an acoustic wave filter employing those SAW resonators.

To achieve a good passband response most, or even all, of the series SAW resonators have their resonant and anti-resonant frequencies bunched up into a tight cluster of frequencies around the desired passband. Instead of setting the pitch distances of the acoustic reflectors 16 based only on the corresponding pitch distances of the IDT electrodes 14, the plurality of SAW resonators 10 in an acoustic wave filter are adjusted relative to one another in that the various pitch distances of the acoustic reflectors 16 are spread relative to each other to more evenly cover the frequency spectrum. This alteration of pitch distances of the acoustic reflectors 16 will have a relatively minor impact on the passband response of the acoustic wave filter, but it can have a substantial impact on the out-of-band response.

Alternatively, it may be possible to implement SAW resonators 10 having acoustic reflectors 16 with a number of electrodes having different electrode widths. While maintaining the same pitch distances for all of the acoustic reflectors 16 of all of the SAW resonators 10, the electrode widths of the acoustic reflectors 16 are adjusted so that the frequency gaps between resonant frequencies of the plurality of first SAW resonators outside the passband of the acoustic wave filter are equalized. This means, that the plurality of SAW resonators 10 in an acoustic wave filter are adjusted relative to one another in that the various electrode widths of the acoustic reflectors 16 are varied relative to each other to more evenly cover the frequency spectrum of the acoustic wave filter. Such a measure will also only have a relatively minor impact on the passband response of the acoustic wave filter, while impacting the out-of-band response substantially.

FIG. 6 is a partial cross-sectional view of a portion of the SAW resonator 10 of any of FIGS. 5A to 5C illustrating a few of the IDT electrodes 14 disposed on the substrate 12. In some embodiments, a SAW resonator 10 may include a multilayer piezoelectric substrate including the piezoelectric substrate 12 and a carrier substrate 22 on which the piezoelectric substrate is disposed. The carrier substrate 22 may be formed of, for example, silicon or a dielectric material, for example, silicon dioxide, aluminum oxide, or sapphire. The carrier substrate 22 is typically thicker than the piezoelectric substrate 12 and provides the acoustic wave resonator with increased mechanical strength.

The piezoelectric substrate 12 may in some implementations include a lithium niobate crystal cut with a surface normal orientation of (α, β, γ), with α between −10° and +10°, β between −10° and +10°, and γ between 80° and 100° in Euler angles. For example, the surface normal orientation of the lithium niobate crystal may be (α, β, γ)=(0°, 0°, 90°) in Euler angles.

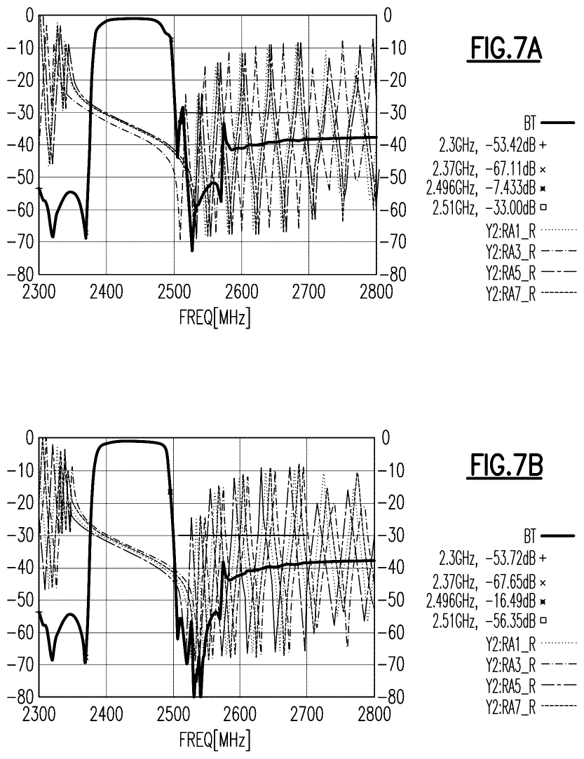

FIG. 7A illustrates as exemplary graph of the admittance values of a conventional acoustic wave filter, i.e. an acoustic wave filter with a number of SAW resonators having the same configuration of acoustic reflectors. FIG. 7B illustrates as exemplary graph of the admittance values of an acoustic wave filter having a number of SAW resonators with adjusted acoustic reflector pitches according to embodiments of this disclosure.

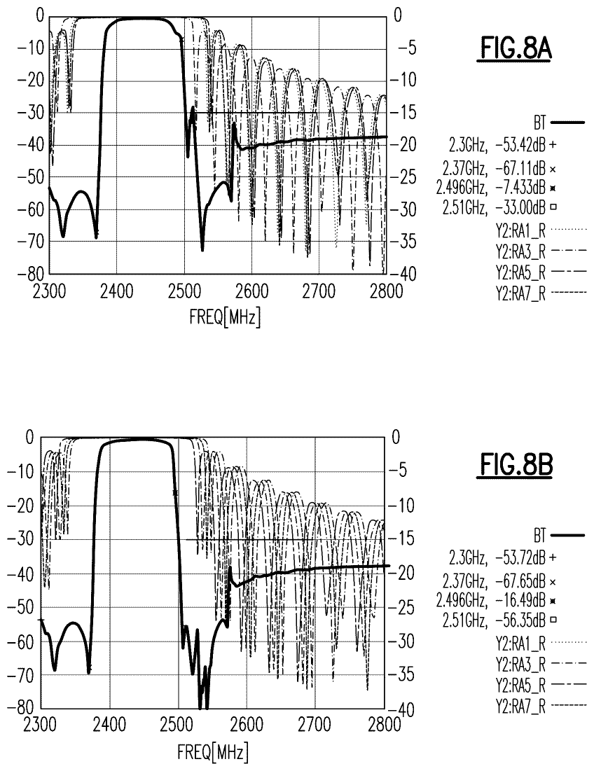

Similarly, FIG. 8A illustrates as exemplary graph of the gain values of a conventional acoustic wave filter, i.e., an acoustic wave filter with a number of SAW resonators having the same configuration of acoustic reflectors. FIG. 8B illustrates as exemplary graph of the gain values of an acoustic wave filter having a number of SAW resonators with adjusted acoustic reflector pitches according to embodiments of this disclosure.

The admittance plots of FIGS. 7A and 7B show the reflectivity of the various Bragg reflectors contained within the series SAW resonators of the acoustic wave filter. Similarly, the gain plots of FIGS. 8A and 8B show the transmissibility of the various Bragg reflectors contained within the series SAW resonators of the acoustic wave filter. As illustrated in FIGS. 7A and 8A, the reflectivity of the Bragg reflectors in the filter with constant pitch distances of the acoustic reflectors of all of the SAW resonators lead to resonant and anti-resonant frequencies outside the passband of the filter to be nearly coinciding for most of the SAW resonators. This leads to less than optimal steepness at the edges of the passband, and thus deterioration of the rejection of RF signals outside the passband frequency range.

On the other hand, as illustrated in FIGS. 7B and 8B, the reflector responses outside the passband of the acoustic wave filter are evenly distributed along the frequency. This is achieved by either spreading the various pitch distances of the acoustic reflectors or spreading the electrode widths of the electrodes of the acoustic reflectors in all of the SAW resonators of the acoustic wave filter relative to each other. As can be seen from FIGS. 7B and 8B, the impact of the alteration of reflector pitch distances or the alteration of reflector electrode widths is only relatively minor in terms of admittance and gain within the passband, but it is large on the admittance and gain in frequency ranges outside the passband. In particular, the steepness at the edges of the passband can be significantly improved, leading to an improvement of the rejection of RF signals outside the passband frequency range.

In some implementations, an architecture, a device and/or a circuit having one or more features described herein can be included in an RF device such as a wireless communication device. Such an architecture, a device and/or a circuit can be implemented directly in the wireless communication device, in one or more modular forms as described herein, or in some combination thereof. In some embodiments, such a wireless communication device can include, for example, a cellular phone, a smart-phone, a hand-held wireless device with or without phone functionality, a wireless tablet, a wireless router, a wireless access point, a wireless base station, etc.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

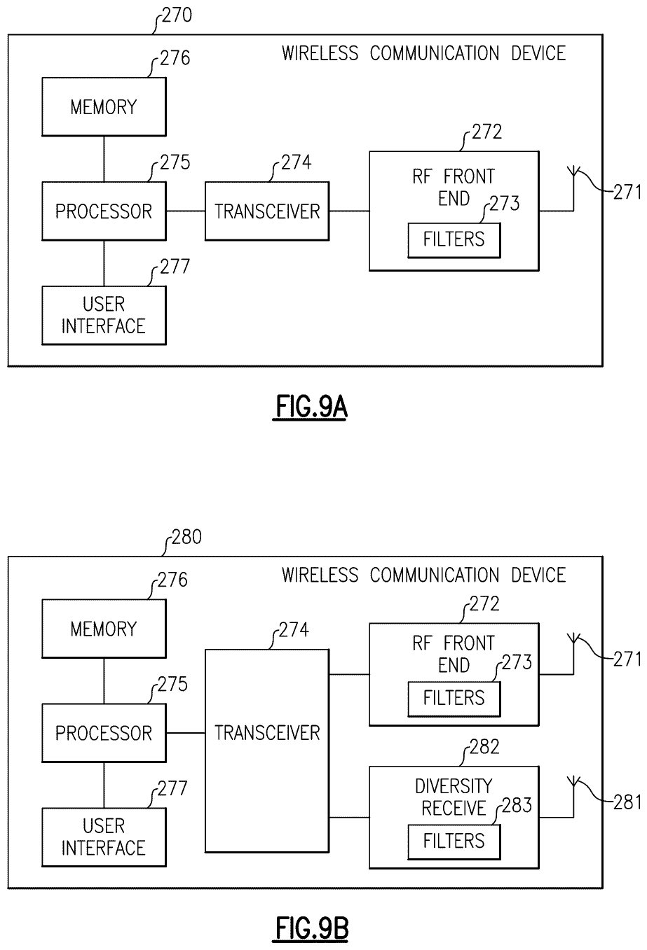

One or more filters with any suitable number of surface acoustic wave resonators having adjusted pitch distances in accordance with any suitable principles and advantages disclosed herein can be implemented in a variety of wireless communication devices. FIG. 9A is a schematic block diagram of an example wireless communication device 270 that includes a filter 273 with one or more surface acoustic wave resonators having adjusted pitch distances in accordance with any suitable principles and advantages disclosed herein. The wireless communication device 270 can be any suitable wireless communication device. For instance, a wireless communication device 270 can be a mobile phone, such as a smart phone. As illustrated, the wireless communication device 270 includes an antenna 271, a radio frequency (RF) front end 272 that includes filter 273, an RF transceiver 274, a processor 275, a memory 276, and a user interface 277. The antenna 271 can transmit RF signals provided by the RF front end 272. The antenna 271 can provide received RF signals to the RF front end 272 for processing.

The RF front end 272 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 272 can transmit and receive RF signals associated with any suitable communication standards. Any of the surface acoustic wave resonators disclosed herein can be implemented in filters 273 of the RF front end 272.

The RF transceiver 274 can provide RF signals to the RF front end 272 for amplification and/or other processing. The RF transceiver 274 can also process an RF signal provided by a low noise amplifier of the RF front end 272. The RF transceiver 274 is in communication with the processor 275. The processor 275 can be a baseband processor. The processor 275 can provide any suitable base band processing functions for the wireless communication device 270. The memory 276 can be accessed by the processor 275. The memory 276 can store any suitable data for the wireless communication device 270. The processor 275 is also in communication with the user interface 277. The user interface 277 can be any suitable user interface, such as a display.

FIG. 9B is a schematic diagram of a wireless communication device 280 that includes filters 273 in a radio frequency front end 272 and second filters 283 in a diversity receive module 282. The wireless communication device 280 is like the wireless communication device 270 of FIG. 9A, except that the wireless communication device 280 also includes diversity receive features. As illustrated in FIG. 9B, the wireless communication device 280 can include a diversity antenna 281, a diversity module 282 configured to process signals received by the diversity antenna 281 and including second filters 283, and a transceiver 274 in communication with both the radio frequency front end 272 and the diversity receive module 282. One or more of the second filters 283 can include one or more surface acoustic wave resonators having adjusted pitch distances in accordance with any suitable principles and advantages disclosed herein.

Surface acoustic wave resonators as disclosed herein can be included in a filter and/or a multiplexer arranged to filter a radio frequency signal in a fifth generation (5G) New Radio (NR) operating band within Frequency Range 1 (FR1). FR1 can go from 410 Megahertz (MHz) to 7.125 Gigahertz (GHz), for example, as specified in a current 5G NR specification. A filter arranged to filter a radio frequency signal in a 5G NR FR1 operating band can include one or more surface acoustic wave resonators implemented in accordance with any suitable principles and advantages disclosed herein. Moreover, surface acoustic wave resonators as disclosed herein can be included in a filter and/or a multiplexer arranged to filter a radio frequency signal in a WiFi operating band, a near-field communication operating band (such as for example, Bluetooth®), or any other suitable radio frequency signal operating band.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

For example, various electronic devices can operate with front-end modules having acoustic wave filters with surface acoustic wave resonators having adjusted pitch distances. For instance, a front-end module having acoustic wave filters with surface acoustic wave resonators having adjusted pitch distances can be included in various electronic devices, including, but not limited to consumer electronic products, parts of the consumer electronic products, electronic test equipment, etc. Example electronic devices include, but are not limited to, a base station, a wireless network access point, a mobile phone (for instance, a smartphone), a tablet, a television, a computer monitor, a computer, a hand-held computer, a personal digital assistant (PDA), a microwave, a refrigerator, an automobile, a stereo system, a disc player, a digital camera, a portable memory chip, a washer, a dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings provided herein can be applied to other systems, not necessarily the systems described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An acoustic wave filter comprising a plurality of first surface acoustic wave (SAW) resonators, each of the plurality of first SAW resonators including a piezoelectric substrate, interdigital transducer electrodes, and acoustic reflectors having a pitch distance, the pitch distances of the acoustic reflectors being adjusted so that the frequency gaps between resonant frequencies of the plurality of first SAW resonators outside the passband of the acoustic wave filter are equalized.

2. The acoustic wave filter of claim 1 wherein the plurality of first SAW resonators are series resonators.

3. The acoustic wave filter of claim 2 further comprising a plurality of second SAW resonators coupled in parallel to the plurality of first SAW resonators.

4. The acoustic wave filter of claim 3 wherein the plurality of second SAW resonators are shunt resonators.

5. The acoustic wave filter of claim 4 wherein the acoustic wave filter is a hybrid ladder-lattice-type acoustic wave filter.

6. The acoustic wave filter of claim 4 wherein the acoustic wave filter is a ladder-type acoustic wave filter.

7. The acoustic wave filter of claim 1 wherein the frequency gaps between resonant frequencies of two neighboring resonators of the plurality of first SAW resonators outside the passband of the acoustic wave filter are substantially equal.

8. The acoustic wave filter of claim 1 wherein the piezoelectric substrate comprises a lithium niobate crystal cut with a surface normal orientation of (α, β, γ), with α between −10° and +10°, β between −10° and +10°, and γ between 80° and 100° in Euler angles.

9. The acoustic wave filter of claim 8 wherein the surface normal orientation of the lithium niobate crystal is (α, β, γ)=(0°, 0°, 90°) in Euler angles.

10. A radio-frequency (RF) module, comprising:
an RF antenna;
a power amplifier coupled to the RF antenna and configured to amplify an RF signal for transmission by the RF antenna; and
at least one acoustic wave filter, the acoustic wave filter including a plurality of first surface acoustic wave (SAW) resonators, each of the plurality of first SAW resonators including a piezoelectric substrate, interdigital transducer electrodes, and acoustic reflectors having a pitch distance, the pitch distances of the acoustic reflectors being adjusted so that the frequency gaps between resonant frequencies of the plurality of first SAW resonators outside the passband of the acoustic wave filter are equalized.

11. The RF module of claim 10 wherein the plurality of first SAW resonators are series resonators.

12. The RF module of claim 11 further comprising a plurality of second SAW resonators coupled in parallel to the plurality of first SAW resonators.

13. The RF module of claim 12 wherein the plurality of second SAW resonators are shunt resonators.

14. The RF module of claim 13 wherein the acoustic wave filter is a hybrid ladder-lattice-type acoustic wave filter.

15. The RF module of claim 14 wherein the acoustic wave filter is a ladder-type acoustic wave filter.

16. The RF module of claim 10 wherein the frequency gaps between resonant frequencies of two neighboring resonators of the plurality of first SAW resonators outside the passband of the acoustic wave filter are substantially equal.

17. The RF module of claim 10 wherein the at least one acoustic wave filter comprises a pre-amplifier acoustic wave filter coupled upstream of the power amplifier in transmit direction and a post-amplifier acoustic wave filter coupled between the power amplifier and the RF antenna.

18. A mobile device comprising an RF module, the RF module including an RF antenna, a power amplifier coupled to the RF antenna and configured to amplify an RF signal for transmission by the RF antenna, and at least one acoustic wave filter, the acoustic wave filter comprising a plurality of first surface acoustic wave (SAW) resonators, each of the plurality of first SAW resonators including a piezoelectric substrate, interdigital transducer electrodes, and acoustic reflectors having a pitch distance, the pitch distances of the acoustic reflectors being adjusted so that the frequency gaps between resonant frequencies of the plurality of first SAW resonators outside the passband of the acoustic wave filter are equalized.

19. The mobile device of claim 18 wherein the at least one acoustic wave filter of the RF module comprises a pre-amplifier acoustic wave filter coupled upstream of the power amplifier in transmit direction.

20. The mobile device of claim 18 wherein the at least one acoustic wave filter of the RF module comprises a post-amplifier acoustic wave filter coupled between the power amplifier and the RF antenna.
